(19) United States
(12) Patent Application Publication
(10) Pub. No.: US 2016/0097830 A1
(43) Pub. Date: Apr. 7, 2016

(54) METHOD AND APPARATUS FOR MAGNETIC RESONANCE FINGERPRINTING

(71) Applicant: Siemens Aktiengesellschaft, Muenchen (DE)

(72) Inventors: David Grodzki, Erlangen (DE); Stefan Huwer, Erlangen (DE); Esther Raithel, Dormitz (DE)

(73) Assignee: Siemens Aktiengesellschaft, Muenchen (DE)

(21) Appl. No.: 14/824,537

(22) Filed: Aug. 12, 2015

(30) Foreign Application Priority Data
Aug. 12, 2014 (DE) 102014215956.3

(51) Int. Cl. G01R 33/56; G01R 33/565

(52) U.S. Cl. CPC G01R 33/5608; G01R 33/56509

(57) ABSTRACT

In order to make it possible to take account of movement of an examination object in a magnetic resonance fingerprinting method, multiple magnetic resonance raw images of an examination area of the examination object are acquired by execution of a magnetic resonance fingerprinting method, multiple magnetic resonance signal waveforms are generated in a processor over different voxels of the multiple magnetic resonance raw images. A signal comparison of the multiple magnetic resonance signal waveforms is made with multiple database signal waveforms stored in a database, with a database value of at least one tissue parameter being logically linked to each database signal waveform of the multiple database signal waveforms. A tissue parameter map is determined on the basis of the result of the signal comparison, wherein said tissue parameter map is movement corrected based on a movement correction. The tissue parameter map is made available at an output of the processor.

### BACKGROUND OF THE INVENTION

1. Field of the Invention

The invention concerns a method for magnetic resonance fingerprinting of an examination object, taking into account movement of the examination object, as well as a magnetic resonance apparatus for implementing such a method.

2. Description of the Prior Art

In a magnetic resonance apparatus, also called a magnetic resonance tomography apparatus, the body of a person to be examined, such as a patient, is usually exposed to a relatively high magnetic field, of 1.5 or 3 or 7 Tesla for example produced by a basic field magnet. In addition gradient pulses are emitted by a gradient coil arrangement. Radio frequency pulses, such as excitation pulses, are then emitted via a radio-frequency radiator by a suitable antenna arrangement, which leads to the nuclear spins of specific atoms being resonantly excited by these radio-frequency pulses being flipped by a defined flip angle in relation to the magnetic field lines of the basic magnetic field. During the relaxation of the nuclear spins, radio-frequency signals, so called magnetic resonance signals, are emitted that are received by suitable radio frequency antennas and then further processed. From the raw data of an examination volume acquired in such a manner, the desired magnetic resonance image data of the examination volume can be reconstructed.

A magnetic resonance fingerprinting method, by means of which quantitative values of tissue parameters of an examination object can be determined, is known from the article by Ma et al., “Magnetic Resonance Fingerprinting”, Nature, 495, 187-192 (14 Mar. 2013).

### SUMMARY OF THE INVENTION

An object of the present invention is to allow a magnetic resonance fingerprinting examination adapted to movement of the examination object.

The invention is based on a method of the magnetic resonance fingerprinting, taking into account a movement of the examination object, which includes the following method steps. A number of magnetic resonance raw images of an examination area of the examination object are acquired by executing a magnetic resonance fingerprinting method. A number of magnetic resonance signal waveforms are generated from the magnetic resonance raw images, with the number of magnetic resonance signal waveforms being formed over different voxels of the multiple magnetic resonance raw images. A signal comparison of the multiple magnetic resonance signal waveforms is made with a number of database signal waveforms stored in a database, with a database value of at least one tissue parameter being logically linked to each database signal waveform of the multiple database signal waveforms. A tissue parameter map movement is generated on the basis of the result of the signal comparison, wherein said tissue parameter map is movement corrected based on a movement correction. The tissue parameter map is then provided in electronic form as a datafile for further use.

The examination object can be a patient, a training person or a phantom. The provision of the tissue parameter map can include an output of the tissue parameter map for viewing by a user on a display unit. As an alternative or in addition the provision of the tissue parameter map can include storage of the tissue parameter map in a database. The tissue parameter map includes a spatially-resolved distribution of the value of the at least one tissue parameter in the examination area. The at least one tissue parameter preferably characterizes a physical characteristic of tissue of the examination object, from which the magnetic resonance signal waveform has been detected. In particular, the at least one tissue parameter can quantify a reaction of the tissue to the radio-frequency excitation. Tissue of the examination object can be, for example, brain tissue, bone tissue, fatty tissue, muscle tissue etc. Naturally tissue parameters for other types of tissue of the examination object appearing sensible to those skilled in the art can be determined.

The at least one tissue parameter can be formed by one or more of the following tissue parameters: A T1 relaxation time, a T2 relaxation time, a diffusion value (for example an apparent diffusion coefficient, ADC), a magnetization moment, a proton density, a resonant frequency, a concentration of a substance, a temperature etc. Naturally further parameters appearing sensible to the person skilled in the art are also conceivable. A number of values of different tissue parameters can also be determined, wherein any given combination of the said tissue parameters is conceivable here.

The acquisition of the multiple magnetic resonance raw images of the examination area typically includes, for each magnetic resonance raw image of the multiple raw images, acquisition of a number of spatially-resolved magnetic resonance signal values. These signal values are in an image area of the examination area. The signal values are not in k-space, i.e. they are not k-space data entries. The magnetic resonance raw images in such cases are typically not intended to be presented on a display screen, for example. The magnetic resonance raw images are exclusively intended to be used as input data for determining the tissue parameter map. The magnetic resonance fingerprinting method includes the setting of different recording parameters for the acquisition of the different magnetic resonance raw images. The recording parameters in this case can be varied in a pseudo-randomized manner. Thus the multiple generated magnetic resonance signal waveforms can represent a pseudo-randomized waveform of the magnetic resonance signals. Possible recording parameters that are changed during the acquisition of the number of magnetic resonance raw images are for example an echo time, a formation and/or number of radio frequency pulses, a formation and/or number of gradient pulses, a diffusion encoding etc. The number of magnetic resonance raw images can in this case be acquired during a number of repetition times, wherein one magnetic resonance raw image of the number of magnetic resonance raw images can be acquired during one repetition time in each case. Thus the multiple magnetic resonance raw images are recorded after one another in time, preferably in a defined timeframe. The multiple magnetic resonance raw images in this case respectively have identical recording (data acquisition) volumes (Field of View, FoV). Thus the multiple magnetic resonance raw images represent a temporal development of the recorded magnetic resonance signals in the recording volume.

Multiple location-dependent magnetic resonance signal waveforms are then generated over the multiple magnetic resonance raw images. The different magnetic resonance signal waveforms preferably generated in each case over corresponding voxels of the respective images of the multiple magnetic resonance raw images. A magnetic resonance signal waveform of the multiple magnetic resonance signal waveforms thus can specify how a signal value of a voxel of the number of voxels changes over the multiple magnetic resonance raw images. Each magnetic resonance signal waveform thus specifies a change of recorded magnetic resonance signal values over the total time of acquisition of the multiple magnetic resonance raw images. The time resolution of the magnetic resonance signal waveforms in this case is the distance in time between the acquisition of two magnetic resonance raw images of the multiple magnetic resonance raw images.

The different database signal waveforms are each assigned a different value of the at least one tissue parameter. Each database signal waveform represents the signal waveform that is to be expected during the magnetic resonance fingerprinting method when a sample, of which the value of the at least one tissue parameter corresponds to the database value, is examined. The database signal waveforms can be established and/or simulated for example in a calibration measurement.

The magnetic resonance fingerprinting method then typically makes provision for a database signal waveform of the number of signal waveforms to be assigned to the acquired magnetic resonance signal waveform on the basis of the result of the signal comparison. In such cases the database signal waveform among the multiple database signal waveforms that has the greatest similarity with the magnetic resonance signal waveform can be assigned to the magnetic resonance signal waveform. The similarity can be established, for example, in a correlation analysis. The database value of the at least one tissue parameter belonging to the assigned database signal waveform can then be set as the measured value of the at least one tissue parameter. The values of the at least one tissue parameter measured at different points in the examination area can then be stored in the tissue parameter map. The tissue parameter map is thus embodied especially locally resolved. The value of the at least one tissue parameter determined on the basis of the signal comparison then especially represents an actual measured value, while the database values of the at least one tissue parameter represent virtual values of the at least one tissue parameter, which means that the database values are not determined in the actual examination of the examination object, but already exist in the database before the actual examination occurs.

The database signal waveforms can also be assigned in each case to a number of database values of a number of tissue parameters. Then, by means of a signal comparison, a number of values of the at least one tissue parameter can be determined simultaneously. Only the acquisition of a single magnetic resonance signal waveform for a voxel of the examination area is necessary in order to determine all values of the number of tissue parameters by means of the magnetic resonance fingerprinting method for the voxel. For a more detailed description of a typical way in which a magnetic resonance fingerprinting method functions the reader is referred to the document by Ma et al. cited above.

The temporally consecutive acquisition of the number of magnetic resonance raw images via which the magnetic resonance signal waveforms are generated can make the magnetic fingerprinting method susceptible to a movement of the examination object. Movement of the examination object in such cases can occur between the acquisition of two magnetic resonance raw images of the number of magnetic resonance raw images. For example a breathing movement and/or a heart movement of the examination object can occur. Deliberate movements of limbs of the examination object can also occur. The movement of the examination object can lead to movement-induced deviations in the generated magnetic resonance signal waveforms. This can then lead to problems during signal comparison of the magnetic resonance signal waveforms that have changed because of the movement, with the database signal waveforms, since the database signal waveforms are not typically based on any movement information. This can lead to incorrect assignments of the at least one tissue parameter. This in turn can lead to a worsening of the expressiveness of the tissue parameter map. In this case the movement of the examination object in the magnetic resonance fingerprinting method especially plays a greater role when the multiple magnetic resonance raw images are recorded over a longer period of time.

Some movement of the examination object can be compensated for during the signal comparison of the number of magnetic resonance signal waveforms with the database signal waveforms. For example, movement can be detected by a pattern recognition algorithm, but then the effectiveness of the correlation depends on the sensitivity of the pattern recognition algorithm with respect to movement. Despite this effort, in this type of movement compensation during the signal comparison, a part of the magnetic resonance signal waveform can remain unconsidered, which leads to a reduction in accuracy of the determined values of the at least one tissue parameter.

Therefore, in accordance with the invention, a dedicated movement correction is used during the magnetic resonance fingerprinting method. This dedicated movement correction goes beyond a possible implicit movement correction during magnetic resonance signal comparison. Advantageously movement correction is decoupled from the magnetic resonance signal comparison. This means especially that movement correction is not undertaken during the signal comparison that is employed for determining the values of the at least one tissue parameter for the tissue parameter map.

Two options are presented for the movement correction in the following sections: The movement correction can be applied either to at least one magnetic resonance raw image, or to at least one magnetic resonance signal waveform. It is also conceivable for both the magnetic resonance raw images and also the magnetic resonance signal waveforms to be movement-corrected. Thus initially a magnetic resonance raw image can be movement-corrected and then the magnetic resonance signal waveform generated can be movement-corrected on the basis of the at least one movement-corrected magnetic resonance raw image. The at least one movement-corrected magnetic resonance raw image and/or the at least one movement-corrected magnetic resonance signal waveform thus can be further processed. Other options for movement correction that appear reasonable to those skilled in the art may also be used.

In this way a magnetic resonance fingerprinting method adapted to movement of the examination object is possible. The dedicated movement correction can lead to an improvement in accounting movement of the examination object compared to movement of the examination object merely being taken into account implicitly during the signal comparison. The inventive movement correction advantageously leads to an increase in the accuracy during the signal comparison, so that more accurate values of the at least one tissue parameter can be determined. Thus the quality and expressiveness of the tissue parameter map can be increased. At the same time the robustness of the magnetic resonance fingerprinting method is improved. It is possible for example by means of the proposed movement correction to assign the magnetic resonance signal waveform correctly even if no sufficiently long time intervals without a movement of the examination object are available. Also with the proposed method rigid and non-rigid movements of the examination object can be compensated for.

In an embodiment, at least a part of the movement correction is undertaken before the method step of signal comparison. The entire movement correction can also take place before the signal comparison. Thus the signal comparison can take place on the basis of the movement-corrected magnetic resonance signal waveforms. For example, the matching database signal waveform can be assigned to the magnetic resonance signal waveform in the signal waveform. The database signal waveform matching the magnetic resonance signal waveform in this case is especially the database signal waveform of the number of database signal waveforms that is based on the same tissue as the magnetic resonance signal waveform.

In another embodiment, the movement correction includes correction of movement of the examination object occurring during the acquisition of the multiple magnetic resonance raw images. Thus the relevant movement of the examination object that occurs during the data acquisition can be movement-corrected.

In another embodiment, the movement correction includes a raw image movement correction of at least one magnetic resonance raw image of the number of magnetic resonance raw images. The raw image movement correction in this case especially includes movement correction of an image content of the at least one magnetic resonance raw image. Thus the raw image movement correction typically takes place in the two-dimensional or three-dimension space.

In another embodiment, the raw image movement correction is applied to the at least one magnetic resonance raw image at least partly before the step of generating the number of magnetic resonance signal waveforms. Thus the at least one movement-corrected magnetic resonance raw image can be included in the generation of the number of magnetic resonance signal waveforms. All magnetic resonance raw images can also be movement-corrected. If only a part of the magnetic resonance raw images is movement-corrected in the raw image movement correction, then the magnetic resonance signal waveform can be generated simultaneously over the non-movement-corrected and the movement-corrected magnetic resonance raw images.

In another embodiment, the movement correction includes a signal waveform movement correction of at least one magnetic resonance signal waveform of the magnetic resonance signal waveforms. The signal waveform movement correction in this case includes a movement correction of the at least one magnetic resonance signal waveform after the generation of the at least one magnetic resonance signal waveform. In this way in the signal waveform movement correction typically the at least one one-dimensional magnetic resonance signal waveform is movement-corrected.

In another embodiment, the signal waveform movement correction is applied at least partly to the at least one magnetic resonance signal waveform before the method step of signal comparison. Thus the signal comparison can be undertaken using the at least one magnetic resonance signal waveform movement-corrected in the signal waveform movement correction. Thus a result of the signal comparison can be improved.

In another embodiment, on the basis of a subset of the number of magnetic resonance raw images, an expected value of the at least one tissue parameter is determined, and the movement correction is undertaken using the expected value of the at least one tissue parameter. The value to be expected of the at least one tissue parameter is especially assigned to a signal waveform to be expected. If the signal waveform to be expected is a specific database signal waveform of the number of database signal waveforms, then the value to be expected of the at least one tissue parameter is the database value of the at least one tissue parameter assigned to the database signal waveform determined. Thus, as an alternative or in addition to the expected value of the at least one tissue parameter, an expected signal waveform can also be determined. The movement can then also be corrected taking into account the expected signal waveform. The expected value of the at least one tissue parameter, which is determined based on a part of the number of magnetic resonance raw images, can offer an estimation for a further value of the at least one tissue parameter which is determined on the basis of the second part of the number of magnetic resonance raw images. If this further value of the at least one tissue parameter deviates from the expected value of the at least one tissue parameter, for example because of the movement of the examination object, this movement can be compensated for such that the further value of the at least one tissue parameter is adapted to the expected value of the at least one tissue parameter. In this case a number of expected values of the at least one tissue parameter for different voxels of the number of magnetic resonance raw images can be generated. The expected value of the at least one tissue parameter can be an estimation for a measured value of the at least one tissue parameter which is created on the basis of a first part of the magnetic resonance raw images. The value of the at least one tissue parameter to be expected can define, especially in conjunction with a standard deviation of the value of the at least one tissue parameter to be expected, a range in which a measured value of the at least one tissue parameter is to be expected without influence of a movement of the examination object. Overall the expected value of the at least one tissue parameter represents an advantageous starting point and/or an advantageous input parameter for carrying out movement correction.

In another embodiment, the determination of the expected value of the at least one tissue parameter includes a generation of a part signal waveform over the subset of the number of magnetic resonance raw images, a part signal comparison of the part signal waveform and the corresponding parts of the number of database signal waveforms and a determination of the expected value of the at least one tissue parameter on the basis of the result of the part signal comparison. Corresponding part areas of two signal waveforms in this case are especially those part areas of the two signal waveforms which have an identical start magnetic resonance raw image and end magnetic resonance raw image. The start magnetic resonance raw image and the end magnetic resonance raw image in such cases especially define the section of the number of magnetic resonance raw images over which the signal waveform is formed. The part signal comparison in this case is especially decoupled from the signal comparison of the number of magnetic resonance signal waveforms with the database signal waveforms. Advantageously the part signal comparison is concluded before the beginning of the signal comparison. Advantageously, for the generation of the part signal comparison, a subset of the number of magnetic resonance raw images is used, in the acquisition of which only a small movement of the examination object occurs. The size of the subset of a number of magnetic resonance raw images in this case is advantageously selected small enough for a movement of the examination object to only have a small influence. At the same time the size of the subset of the number of magnetic resonance raw images is advantageously selected large enough for a sufficiently accurate determination of the expected value of the at least one tissue parameter to be able to be undertaken. The expected value of the at least one tissue parameter is then especially the database value of the at least one tissue parameter which is logically linked to the database signal waveform established in the part signal comparison. Thus the determination of the expected value of the at least one tissue parameter is especially undertaken in a similar manner to the determination of the tissue parameter map described at the start, with the difference that only corresponding sections of the signal waveforms are considered in each case. Thus a reliable value of at least one tissue parameter can be determined especially simply.

In another embodiment, the signal waveform movement correction includes tissue parameter comparison of a value determined on the basis of a sub-part of the at least one magnetic resonance signal waveform of the at least one tissue parameter with the expected value of the at least one tissue parameter, and correction of the sub-part of the at least one magnetic resonance signal waveform on the basis of the result of the tissue parameter comparison. A subset of the magnetic resonance raw images underlying this sub-part of the at least one magnetic resonance signal waveform in this case is different from the subset of the magnetic resonance raw images underlying the sub-part signal waveform. The subset of the magnetic resonance raw images underlying the sub-part of the at least one magnetic resonance signal waveform is preferably disjoint from the subset of the magnetic resonance raw images underlying the sub-part signal waveform. The sub-part signal waveform can be used in this way to determine the expected value of the at least one tissue parameter. The expected value of the at least one tissue parameter can be used for correction of the sub-part of the at least one magnetic resonance signal waveform. The tissue parameter comparison preferably includes a determination of the deviation of the determined value of the at least one tissue parameter from the expected value of the at least one tissue parameter. If a deviation of values of the at least one tissue parameter is present, this may be caused by a movement of the examination object. Thus portions of the at least one magnetic resonance signal waveform can be identified that have a signal waveform deviating from an expected signal waveform. Such sub-part of the at least one magnetic resonance signal waveform are called deviating sub-parts. These deviating sub-parts can then be corrected. For example, it is possible simply not to take the deviating sub-parts into account in the subsequent signal comparison. The correction of the sub-parts of the at least one magnetic resonance signal waveform can include a replacement or removal of the part area of the at least one magnetic resonance signal waveform if a deviation is established in the tissue parameter comparison. Thus the signal comparison can be carried out using a larger database and an improved tissue parameter map can be determined.

In another embodiment, the correction of the sub-part of the at least one magnetic resonance signal waveform is undertaken using an ambient magnetic resonance signal waveform, which has been acquired in the spatial environment of the at least one magnetic resonance signal waveform. A deviating sub-part as described above can be corrected in this way. The sub-part in such cases can be corrected such by replacing it with a corresponding section of the ambient magnetic resonance signal waveform. Thus the sub-part of the at least one magnetic resonance signal waveform can be replaced by a corresponding replacement sub-part of the ambient magnetic resonance signal waveform. A value of the at least one tissue parameter based on the replacement sub-part is then matched to the expected value of the at least one tissue parameter better than a value of the at least one tissue parameter based on the part area. The spatial environment of the at least one magnetic resonance signal waveform can include a number of candidate ambient magnetic resonance signal waveforms that have been acquired at a maximum spatial distance from the magnetic resonance signal waveform. This maximum distance can be determined by a typical movement of the examination object that is to be expected. Thus, if a flat breathing movement of the examination object is to be compensated, the maximum distance can be smaller than when movement of a limb of the examination object is to be compensated. Within this maximum distance the ambient magnetic resonance signal waveform of the number of potential ambient magnetic resonance signal waveforms can then be determined that is best suited for correction of the sub-part of the at least one magnetic resonance signal waveform. For the determination of the suitable ambient magnetic resonance signal waveforms once again a part signal comparison of an expected database signal waveform logically linked to with the value of the at least one tissue parameter to be expected can be undertaken. Once determined, a spatial transformation specification for mapping a sub-part of an ambient magnetic resonance signal waveform onto the sub-part of the at least one magnetic resonance signal waveform can also be used for a correction of other magnetic resonance signal waveforms. Thus the sub-part of the at least one magnetic resonance signal waveform can be corrected especially effectively.

In another embodiment, the raw image movement correction includes a first position of the examination object in a first magnetic resonance raw image of the multiple magnetic resonance raw images, identifying a second position of the examination object in the at least one magnetic resonance raw image, and transforming the at least one magnetic resonance raw image on the basis of the recognized first positioning and second positioning. The raw image movement correction described below can be employed independently from the signal waveform movement correction described in previous sections. As an alternative, the raw image movement correction described in the following sections can be used combined with the signal waveform movement correction described in the previous section. The positioning of the examination object can for example be determined by means of edge detection and/or using mutual information-based optimization approaches. Further methods for determining the position of the examination object that appear reasonable to those skilled in the art are also conceivable. The transformation of the at least one magnetic resonance raw image is carried out such that the positioning of the examination object in the transformed at least one magnetic resonance raw image is adapted to the positioning of the examination object. The transformation of the at least one magnetic resonance raw image can be undertaken by a rigid registration using a rotation matrix and a translation matrix. This procedure is advantageous above all for a rigid body movement, for example of the head and/or brain of the examination object and/or for a large number of slices of the at least one magnetic resonance raw image. A non-rigid registration can also be carried out for determining the transformation, in order for example to correct a movement of the stomach of the examination object. The correction of a change of positioning of the examination object can also include a correction of a change of positioning of the organs of the examination object. The magnetic resonance raw image transformed in this way can be used in the generation of the magnetic resonance waveform. Thus the magnetic resonance waveform can be especially advantageously adapted to the change in a positioning of the examination object during the acquisition of the magnetic resonance raw images.

In another embodiment, the transformation of the at least one magnetic resonance raw image is done using a transformation specification, wherein the transformation specification is determined on the basis of the recognized first positioning, the second positioning and on the basis of the expected value of the at least one tissue parameter. For this purpose, the expected value of the at least one tissue parameter is determined before the raw image movement correction. The expected value of the at least one tissue parameter can represent an especially advantageous additional parameter in the determination of the transformation of the at least one magnetic resonance raw image. The expected value of the at least one tissue parameter can thus be employed in the raw image movement correction.

In another embodiment, the expected value of the at least one tissue parameter is included in a regularization term used in the determination of the transformation specification such that a further value of the at least one tissue parameter which is determined on the basis of a magnetic resonance signal waveform generated using the transformed at least one magnetic resonance raw image matches as accurately as possible the expected value of the at least one tissue parameter. In this way the transformation specification can be established for transformation of the at least one magnetic resonance raw image. It is conceivable for the expected value of the at least one tissue parameter to be included as a penalty term in the regularization term. The penalty term, for example, can penalize a deviation, introduced because of the movement of the examination object, of a specific value of the at least one tissue parameter from the expected value of the at least one tissue parameter. Thus such a transformation of the at least one magnetic resonance raw image can be prevented. Equally here, based on the expected database signal waveform logically linked to the expected value of the at least one tissue parameter, a signal waveform-based measure of similarity can be used to determine the transformation of the at least one magnetic resonance raw image. Thus the raw image movement correction and the signal waveform movement correction can be carried out especially advantageously integrated. At the same time it is conceivable, for predicting the movement of the examination object, to introduce a movement model of the examination object.

Furthermore the invention concerns a magnetic resonance apparatus with a raw image acquisition unit (scanner), a computer and an output interface, wherein the computer includes a signal waveform generation computing stage, a signal comparison computing stage, a determination computing stage and a movement computing stage. The components of the magnetic resonance apparatus are designed to implement the inventive method.

Thus the magnetic resonance apparatus is configured to carry out a method for magnetic resonance fingerprinting of an examination object, taking into account movement of the examination object. The raw image acquisition scanner is operated for acquiring multiple magnetic resonance raw images of an examination area of the examination object by execution of a magnetic resonance fingerprinting method. The signal waveform generation computing stage is configured to generate multiple magnetic resonance signal waveforms from the magnetic resonance raw images, wherein the multiple magnetic resonance signal waveforms are formed over different voxels of the multiple magnetic resonance raw images. The signal comparison computing stage is configured for signal comparison of the multiple magnetic resonance signal waveforms with multiple database signal waveforms stored in a database, with a database value of at least one tissue parameter being logically linked to each database signal waveform of the multiple database signal waveforms. The determination computing stage is configured to determine a tissue parameter map on the basis of the result of the signal comparison. The movement correction computing stage is configured to carry out a movement correction of the tissue parameter map so that the tissue parameter map is movement-corrected. The output interface provides the tissue parameter map as an output in the form of an electrical signal representing a datafile that can be further used.

In an embodiment of the magnetic resonance apparatus, the movement correction computing stage is configured to undertake at least a part of the movement correction before the method step of the signal comparison.

In another embodiment of the magnetic resonance apparatus, the movement correction computing stage is configured to include, in the movement correction, a correction of a movement of the examination object that occurs during the acquisition of multiple magnetic resonance raw images.

In another embodiment of the magnetic resonance apparatus, the movement correction computing stage is configured to include in the movement correction, a raw image movement correction of at least one magnetic resonance raw image of the multiple magnetic resonance raw images.

In another embodiment of the magnetic resonance apparatus, the movement correction computing stage is configured to apply the raw image movement correction to the at least one magnetic resonance raw image at least partly before the method step of generating the multiple magnetic resonance signal waveforms.

In another embodiment of the magnetic resonance apparatus, the movement correction computing stage is configured to include, in the movement correction, a signal waveform movement correction of at least one magnetic resonance signal waveform of the magnetic resonance signal waveforms.

In another embodiment of the magnetic resonance apparatus, the movement correction computing stage is configured to apply the signal waveform movement correction at least partly to the at least one magnetic resonance signal waveform before the method step of signal comparison.

In another embodiment, the movement correction computing stage is configured to determine, an expected value of the at least one tissue parameter on the basis of a subset of the number of magnetic resonance raw images, and to undertake the movement correction using the expected value of the at least one tissue parameter.

In another embodiment of the magnetic resonance apparatus, the signal waveform generation computing stage, the signal comparison computing stage and the movement correction computing stage are configured, in the determination of the expected value of the at least one tissue parameter, to generate a sub-part signal waveform over the subset of the multiple magnetic resonance raw images, and to compare a sub-part signal of the sub-part signal waveform with the corresponding sub-parts of the multiple database signal waveforms, and to determine the expected value of the at least one tissue parameter on the basis of the results of the sub-part signal comparison.

In another embodiment of the magnetic resonance apparatus, the signal comparison computing stage and the movement correction computing stage are configured to implement the signal comparison movement correction by a tissue parameter comparison of a value of the at least one tissue parameter determined on the basis of a sub-part of the at least one magnetic resonance signal waveform with the expected value of the at least one tissue parameter, and correction of the sub-part of the at least one magnetic resonance signal waveform on the basis of the results of the tissue parameter comparison.

In another embodiment of the magnetic resonance apparatus, the movement detection computing stage is configured to undertake the correction of the sub-part of the at least one magnetic resonance signal waveform using an ambient magnetic resonance signal waveform, which has been acquired in the spatial environment of the at least one magnetic resonance signal waveform.

In another embodiment of the magnetic resonance apparatus, the movement detection computing stage is configured to implement the raw image movement correction by a detection of the a position of the examination object in a first magnetic resonance raw image of the multiple magnetic resonance raw images, detection of a second position of the examination object in at least one magnetic resonance raw image, and a transformation of the at least one magnetic resonance raw image on the basis of the detected first position and second position.

In another embodiment of the magnetic resonance apparatus, the movement detection computing stage is configured to undertake the transformation of the at least one magnetic resonance raw image using a transformation specification, wherein the transformation specification is determined on the basis of the recognized first position, the second position, and on the basis of the expected value of the at least one tissue parameter.

In another embodiment of the magnetic resonance apparatus, the movement detection computing stage is configured to include the expected value of the at least one tissue parameter in a regularization term used in the determination of the transformation specification, such that a further value of the at least one tissue parameter, which is determined on the basis of a magnetic resonance signal waveform generated using the transformed at least one magnetic resonance raw image, matches the expected value of the at least one tissue parameter as accurately as possible.

The advantages of the inventive magnetic resonance apparatus correspond to the advantages of the inventive method as described above. Features, advantages, and alternate forms of embodiment of the method are applicable as well. The functional features of the method are embodied in corresponding physical modules, such as hardware modules of the apparatus.

### BRIEF DESCRIPTION OF THE DRAWINGS

FIG. 1 shows an inventive magnetic resonance device in a schematic diagram.

FIG. 2 is a flowchart of a first form of embodiment of the inventive method.

FIG. 3 is a flowchart of a second form of embodiment of the inventive method,

FIG. 4 is a flowchart of a third embodiment of the inventive method.

### DESCRIPTION OF THE PREFERRED EMBODIMENTS

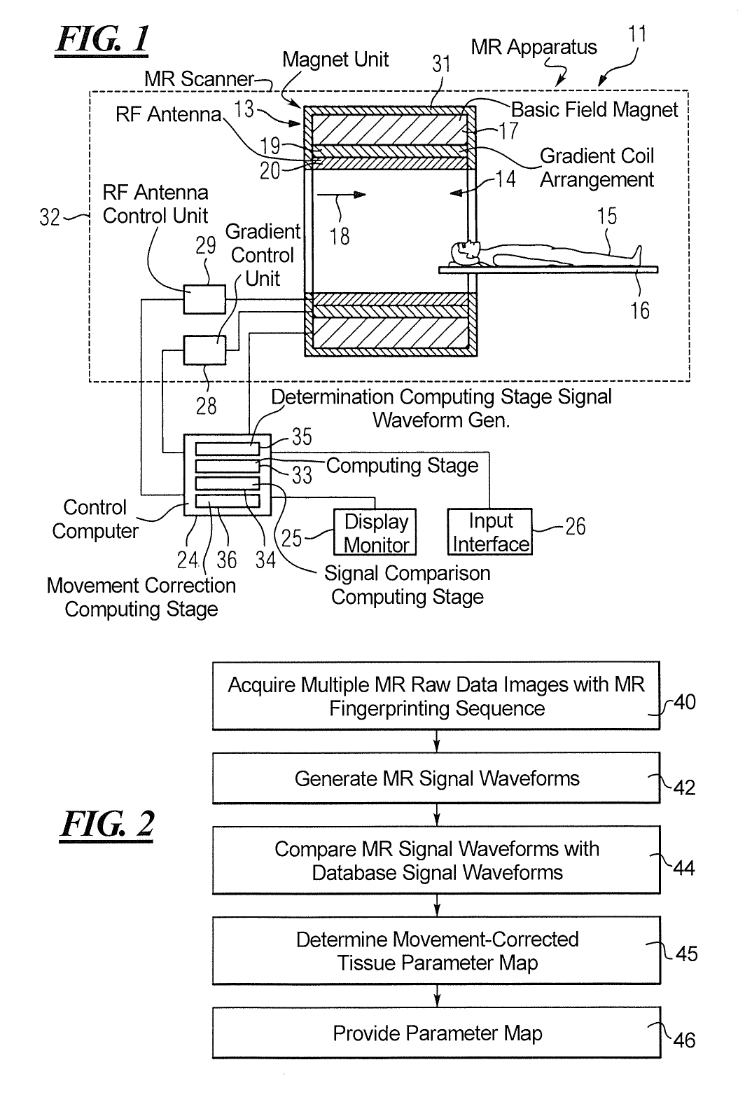

FIG. 1 is a schematic illustration of an inventive magnetic resonance apparatus 11. The magnetic resonance apparatus 11 has a magnet unit 13 with a basic field magnet 17 for creating a strong and constant basic magnetic field 18. The magnet unit 13 has a cylindrical patient receiving area 14 for receiving an examination object 15, in the present case a patient 15. The patient receiving area 14 is enclosed in a circumferential direction cylindrically by the magnet unit 13. The patient 15 can be pushed by a patient support 16 of the magnetic resonance apparatus 11 into the patient receiving area 14. The patient support 16 has a couch for this purpose, which is movably mounted within the magnet unit 13. The magnet unit 13 is shielded by a housing cladding 31.

The magnet unit 13 also has a gradient coil arrangement 19 for creating magnetic field gradients, which are used for spatial encoding during imaging. The gradient coil arrangement 19 is activated by a gradient control unit 28. Furthermore the magnet unit 13 has a radio-frequency (RF) antenna 20, which is designed in the exemplary embodiment shown as a body coil integrated at a fixed location into the magnet unit 13, and a radio-frequency antenna control unit 29 that operates the radio-frequency antenna 20 so as to radiate radio-frequency pulses in a magnetic resonance data acquisition sequence into an examination area, which is essentially formed by the patient receiving area 14. The radio-frequency pulses cause nuclear spins in the patient 15 to be resonantly excited so as to be “flipped” from alignment with the basic magnetic field. As the spins relax, they emit radio-frequency signals, as magnetic resonance signals. The radio-frequency antenna 20 is further embodied for receiving the magnetic resonance signals from the patient 15.

To control the basic field magnet 17, the gradient control unit 28 and the radio-frequency antenna control unit 29, the magnetic resonance device 11 has a control computer 24. The control computer 24 controls the magnetic resonance apparatus 11 centrally, such as, for example, to execute a predetermined gradient echo imaging sequence. Control information such as imaging parameters, and reconstructed magnetic resonance images, can be provided for a user via an output interface, in the present case a display monitor 25. The magnetic resonance apparatus 11 has an input interface 26 via which information and/or parameters can be entered by a user during a data acquisition procedure. The control computer 24 can include the gradient control unit 28 and/or radio-frequency antenna control unit 29 and/or the display monitor 25 and/or the input interface 26.

In the shown exemplary embodiment, the control computer 24 includes a signal waveform generation computing stage 33, a signal comparison computing stage 34, a determination computing stage 35, and a movement correction computing stage 36. The movement correction computing stage 36 can include a raw image movement correction computing stage (not shown) and/or a signal waveform movement correction computing stage (not shown). Each of the computing stages is a portion of the overall computer circuitry of the control computer 24, or is a routine within the software that open after the control computer 24.

The magnetic resonance apparatus 11 further includes a raw image acquisition unit scanner 32. The raw image acquisition unit 32 is formed by the magnet unit 13 together with the radio-frequency antenna control unit 29 and the gradient control unit 28. The magnetic resonance apparatus 11 is thus designed, together with the raw image acquisition unit 32, the control computer 24 and the output interface 25, for implementing the inventive method.

The magnetic resonance apparatus 11 shown can naturally include other components that magnetic resonance apparatuses normally have. The general way in which a magnetic resonance apparatus 11 functions is known to those skilled in the art, so that a detailed description of the further components need not be provided herein.

FIG. 2 shows a flowchart of a first embodiment of an inventive method for magnetic resonance fingerprinting of an examination object 15, taking into consideration movement of the examination object 15.

In a first method step 40, the raw image acquisition unit 32 acquires multiple magnetic resonance raw images of an examination area of the examination object 15 by execution of a magnetic fingerprinting method. The magnetic resonance fingerprinting method in such cases includes, during the recording of the magnetic resonance raw images, the use of recording parameters that change in a pseudo-randomized manner.

In a further method step 42 a number of magnetic resonance signal waveforms are generated over the magnetic resonance raw images by the signal waveform generation computing stage 33, wherein the multiple magnetic resonance signal waveforms are formed over different voxels of the multiple magnetic resonance raw images. The signal waveform over the multiple magnetic resonance raw images is formed over each voxel of the magnetic resonance raw images.

In a further method step 44, the signal comparison computing stage 34 carries out signal comparison of the multiple magnetic resonance signal waveforms with multiple database signal waveforms stored in a database, with a database value of at least one tissue parameter being logically linked to each database signal waveform of the multiple database signal waveforms. The database in this case is accessible by the control computer 24 for the purposes of exchanging data. Each of the database signal waveforms is typically assigned a database value of at least one tissue parameter. The magnetic resonance signal waveforms are compared with each of the database signal waveforms. The signal comparison can be done by a conventional pattern recognition method and/or by a correlation analysis. In the signal comparison, a comparison parameter is then produced for each comparison, which characterizes the degree to which the respective magnetic resonance signal waveforms match the respective database signal waveforms.

In a further method step 45, the determination computing stage 35 determines a movement-corrected tissue parameter map on the basis of the result of the signal comparison. For this purpose, a movement correction of the tissue parameter maps by the movement correction computing stage 36 has occurred. Movement of the examination object 15 that has occurred during the acquisition of the number of magnetic resonance raw images is then taken into consideration in the movement-corrected tissue parameter map. The content of the tissue parameter map is determined, for example, by a matching database signal waveform of the multiple database signal waveforms being established for each magnetic resonance signal waveform. The matching database signal waveform is the database signal waveform that has the greatest match with the magnetic resonance signal waveform. The database value of the at least one tissue parameter that is logically linked to the matching database signal waveform is then inserted into the tissue parameter map.

In a further method step 46, the tissue parameter map is provided by the output interface 25. In the shown embodiment, the tissue parameter map is displayed, so the output interface 25 is (or has) a display monitor. It is also conceivable for the tissue parameter map to be stored in a database via the output interfaces.

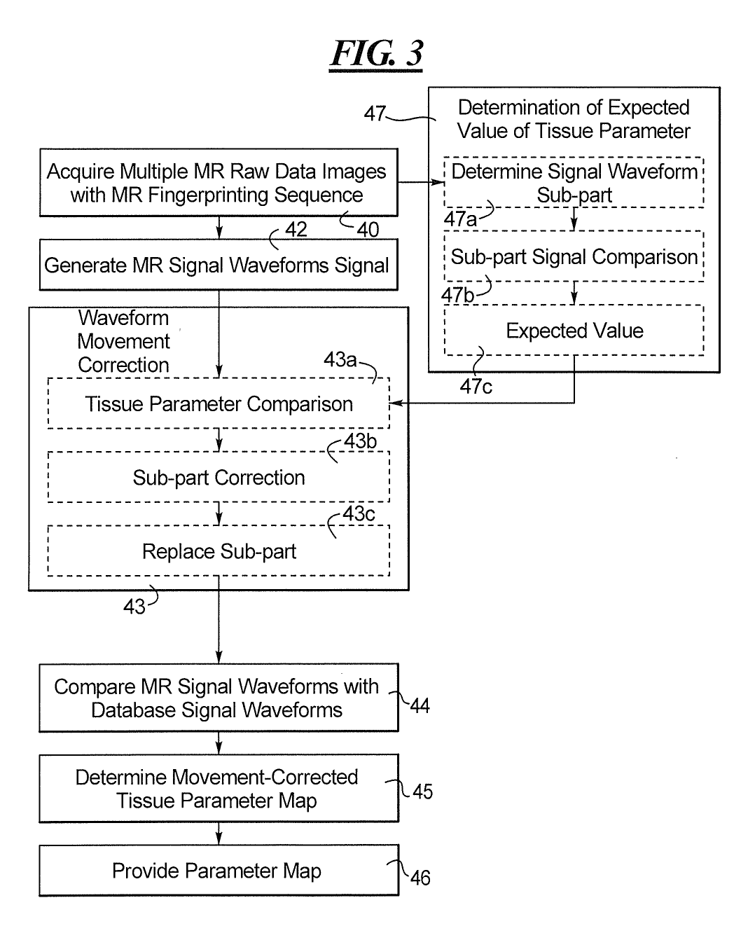

FIG. 3 shows a flowchart of a second embodiment of an inventive method for magnetic resonance fingerprinting of an examination object 15, taking into consideration movement of the examination object 15.

The description given below is essentially restricted to the differences from the exemplary embodiment in FIG. 2, wherein method steps that essentially remain the same are given the same reference numbers.

The second embodiment of the inventive method shown in FIG. 3 includes the method steps 40, 42, 44, 45, 46 of the first embodiment of the inventive method according to FIG. 2. The second embodiment of the inventive method shown in FIG. 3 has additional method steps and substeps. An alternate method sequence to that shown in FIG. 3 is also conceivable, which has only some of the additional method steps and/or substeps shown in FIG. 2. Naturally an alternate method sequence to that shown in FIG. 3 can also have additional method steps and/or substeps.

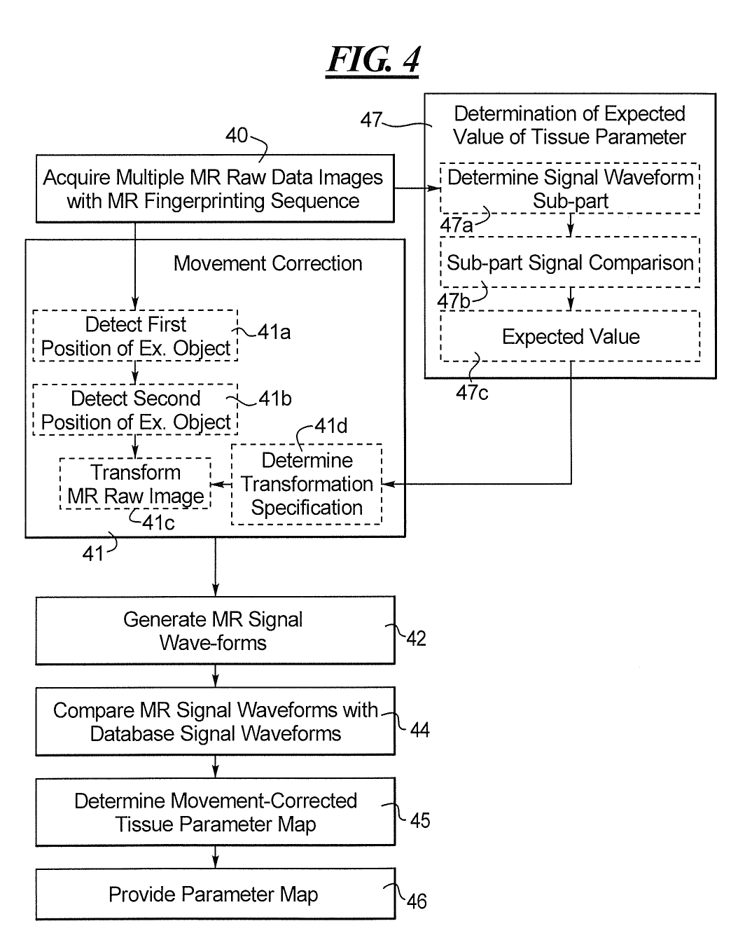

The signal waveform movement correction of the at least one magnetic resonance signal waveform is described in the second exemplary embodiment shown in FIG. 3. It is also conceivable for the signal waveform movement correction shown in FIG. 3 to be used combined with the raw image movement correction shown in FIG. 4.

The further method step 42 is followed by a further method step 43, in which the movement correction computing stage 36 takes account of the movement of the examination object 15 during the acquisition of the multiple magnetic resonance raw images by a signal waveform movement correction of at least one magnetic resonance signal waveform of the multiple magnetic resonance signal waveforms.

In the shown embodiment, the signal waveform movement correction occurs entirely before a signal comparison in a further method step 44. Thus the signal waveform movement correction is applied to the at least one magnetic resonance signal waveform before the signal comparison in the further method step 42. The signal waveform movement correction can also be done only partly before the signal comparison. The arrangement of the second optional method step 43 shown is only to an example, although it is especially advantageous as shown.

In a further method step 47, an expected value of the at least one tissue parameter is determined on the basis of a subset of the number of magnetic resonance raw images by the movement correction computing stage 36. The expected value of the at least one tissue parameter is especially determined for each voxel of the magnetic resonance raw image. At this point the determination of the value of the at least one tissue parameter for a voxel is described as an example.

For this purpose, in a first substep 47a of the further method step 47, a sub-part signal waveform is determined for this voxel over the subset of the multiple magnetic resonance raw images. This sub-part signal waveform represents a section of the magnetic resonance signal waveform acquired at the voxel.

In a second substep 47b of the further method step 47, there is a sub-part signal comparison of the sub-part signal waveform with a corresponding sub-part of the multiple database signal waveforms. For the sub-part signal comparison, sections of the database signal waveforms are used. In the sub-part signal comparison, a matching database signal waveform is established that has the section (sub-part) that best correlates with the sub-part signal waveform for example.

In a third substep 47c of the further method step 47, the expected value of the at least one tissue parameter is determined for this voxel on the basis of the result of the sub-part signal comparison. The database value of the at least one tissue parameter logically linked to the matching database signal waveform can be set as the expected value of the at least one tissue parameter.

This process can be repeated for each voxel of the multiple magnetic resonance raw images, so that, for each voxel of the multiple magnetic resonance raw images, an expected value of the at least one tissue parameter is determined. It is also advantageous to determine a number of expected values of the at least one tissue parameter for an individual voxel on the basis of different subsets of the number of magnetic resonance raw images. Thus, on the basis of a sliding window, consecutive magnetic resonance raw images in each case can be employed for determining different values of the at least one tissue parameter. It is also conceivable as an alternative or in addition for an expected value range of the at least one tissue parameter to be determined on the basis of statistical modeling, for example using an iterative Gaussian estimation of expected value and standard deviation of the expected tissue parameter. In order to obtain better estimates the expected values of the at least one tissue parameter, it is also conceivable for a filtering of the estimation, for example by a Kalman filter, to be undertaken.

The signal waveform movement correction in the further method step 43 is undertaken, taking into consideration the expected value of the at least one tissue parameter.

For this purpose, in a first substep 43a of the further method step 43, a tissue parameter comparison is undertaken of a value of at least one tissue parameter, determined on the basis of a sub-part of the at least one magnetic resonance signal waveform, with the expected value of the at least one tissue parameter. It can be established, for example, whether the value of the at least one tissue parameter determined on the basis of the part area of the at least one magnetic resonance signal waveform matches the expected value of the at least one tissue parameter or is at least similar to said value. If this is not the case the deviation because of the movement of the examination object 15 can be present.

Thus, in a second substep 43b of the further method step 43, there can be a correction of the sub-part of the at least one magnetic resonance signal waveform on the basis of the result of the tissue parameter comparison, for example the sub-part of the at least one magnetic resonance signal waveform can be excluded in a following signal comparison of the at least one magnetic resonance signal waveform with the database signal waveforms for determining the tissue parameter map.

It is, however, advantageous for the correction of the part area of the at least one magnetic resonance signal waveform to be undertaken using an ambient magnetic resonance signal waveform, which has been acquired in the spatial environment of the at least one magnetic resonance signal waveform. Thus, in a third substep 43c of the further method step 43, the sub-part of the magnetic resonance signal waveform can be replaced by a corresponding sub-part of the ambient magnetic resonance signal waveform. Thus ,for example, a spatial assignment of the ambience magnetic resonance signal waveform to the at least one magnetic resonance signal waveform can be made. This spatial assignment can be described by a translation specification, for example. This translation specification, once determined, can also be used to map other ambient magnetic resonance signal waveforms onto other magnetic resonance signal waveforms in order to correct part areas of the other magnetic resonance signal waveforms.

The at least one magnetic resonance signal waveform movement-corrected in this way, can be compared in a further method step 44 with the database signal waveforms for determining a value of the tissue parameter map.

FIG. 4 is a flowchart of a third embodiment of the inventive method for magnetic resonance fingerprinting of an examination object 15, taking into consideration a movement of the examination object 15.

The description given below is essentially restricted to the differences from the exemplary embodiment in FIG. 2, wherein method steps that essentially remain the same are given the same reference numbers.

The third embodiment of the inventive method shown in FIG. 4 includes the method steps 40, 42, 44, 45, 46 of the first embodiment of the inventive method according to FIG. 2. In addition, the third form of embodiment of the inventive method shown in FIG. 4 contains method step 47 with substeps 47a, 47b and 47c from the second embodiment of the inventive method according to FIG. 3. In addition, the third form of embodiment of the inventive method shown in FIG. 4 contains additional method steps and substeps. An alternate method sequence to that shown in FIG. 4, which only contains some of the additional method steps and/or substeps shown in FIG. 4, is also conceivable. Naturally an alternate method sequence to that shown in FIG. 4 can also have additional method steps and/or substeps.

In the third exemplary embodiment shown in FIG. 4 the raw image movement correction of the at least one magnetic resonance raw image is described. It is also conceivable for the raw image movement correction shown in FIG. 4 to be used combined with the signal waveform movement correction shown in FIG. 3.

The first method step 40 is followed by a further method step 41 in which the movement correction unit takes into account a movement of the examination object during the acquisition of the number of magnetic resonance raw images by means of raw image movement correction of at least one magnetic resonance raw image. Naturally it is also conceivable for both the raw image movement correction to be done in the first optional method step 41 and also the signal waveform movement correction in the second optional method step 43.

In the case shown the raw image movement is corrected completely before a signal comparison in a further method step 42. Thus the raw image movement correction is applied to the at least one magnetic resonance raw image before the generation of the number of magnetic resonance signal waveforms in the further method step 42. The raw image movement correction can also be undertaken only partly before the signal comparison. The arrangement of the first optional method step shown is only to be seen as an example, even if it is especially advantageous as shown. The raw image movement correction in this case can especially include a movement correction of an image content of the magnetic resonance raw images.

The raw image movement correction in further method step 41 is undertaken taking into consideration the expected value of the at least one tissue parameter. The expected value of the at least one tissue parameter in this case is determined in further method step 47, by a method as described in FIG. 3 for example.

The further method step 41 in this case includes a first substep 41a, in which a first position of the examination object 15 is detected in a first magnetic resonance raw image of the multiple magnetic resonance raw images.

In a second substep 41b of the further method step 41, a second position of the examination object in the at least one magnetic resonance raw image which is to be corrected is detected. The first magnetic resonance raw image in this case has especially been recorded in a phase of little movement of the examination object 15. Thus it can advantageously represent a reference image for correction of the movement in the at least one magnetic resonance raw image.

In a third substep 41c of the further method step 41 the transformation of the at least one magnetic resonance raw image on the basis of the detected first positioning and the second positioning is then undertaken. The magnetic resonance raw image can be movement-corrected by means of the transformation.

The transformation of the at least one magnetic resonance raw image is undertaken using a transformation specification, wherein the transformation specification is determined in a fourth substep 41d of the further method step 41 on the basis of the detected first positioning, the detected second positioning and on the basis of the expected value of the at least one tissue parameter.

It is advantageous for the expected value of the at least one tissue parameter to be included in a regularization term used in the determination of the transformation specification. The regularization term is advantageously embodied such that a further value of the at least one tissue parameter which is determined on the basis of a magnetic resonance signal waveform generated using the transformed at least one magnetic resonance image, matches the expected value of the at least one tissue parameter as accurately as possible.

Naturally the expected value of the at least one tissue parameter can also be included in another way into the determination of the transformation specification. For example a signal waveform-based measure of similarity can also be used for determining the transformation specification. The signal waveform-based measure of similarity can be based in such cases on an expected database signal waveform logically linked to the expected value of the at least one tissue parameter.

The at least one magnetic resonance raw image movement-corrected in this way can be included in the generation of the magnetic resonance signal waveforms in further method step 42.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for magnetic resonance (MR) fingerprinting with movement correction of an examination object, comprising:
operating an MR scanner, while an examination object is situated in the MR scanner, according to an MR fingerprinting sequence to acquire a plurality of MR raw images of an examination area of the examination object;
providing said MR raw images to a processor and, in said processor, generating a plurality of MR signal waveforms from the MR raw images, with the plurality of MR signal waveforms being formed over different voxels of the plurality of MR raw images;
from said processor, accessing a database in which a plurality of database signal waveforms are stored that are logically linked in said database respectively to a database value of at least one tissue parameter and comparing said plurality of MR signal waveforms with said plurality of database signal waveforms to obtain a comparison result;
in said processor, generating a tissue parameter map based on said comparison result, wherein said tissue parameter map is movement corrected based on a movement correction; and
making said tissue parameter map available at an output of the processor in electronic form, as a datafile.

2. A method as claimed in claim 1 comprising executing said movement correction in said processor before comparing said plurality of MR signal waveforms with said plurality of data signal waveforms.

3. A method as claimed in claim 1 comprising implementing said movement correction as a correction of movement of the examination object that occurs during acquisition of said plurality of MR raw images.

4. A method as claimed in claim 1 comprising implementing said movement correction as a raw image movement correction of at least one of said MR raw images among said plurality of MR raw images.

5. A method as claimed in claim 4 comprising implementing at least a portion of said raw image movement correction of said at least one MR raw image before generating said plurality of MR signal waveforms.

6. A method as claimed in claim 1 comprising implementing said movement correction to include a signal waveform movement correction of at least one MR signal waveform of said plurality of MR signal waveforms.

7. A method as claimed in claim 6 comprising implementing at least a portion of said signal waveform movement correction before comparing said plurality of MR signal waveforms with said plurality of database signal waveforms.

8. A method as claimed in claim 1 comprising, in said processor, generating an expected value of said at least one tissue parameter from a subset of said plurality of MR raw images, and implementing said movement correction using said expected value of said at least one tissue parameter.

9. A method as claimed in claim 8 comprising determining said expected value of said at least one tissue parameter by generating a sub-part signal waveform over said subset of said plurality of MR raw images, and implementing a sub-part signal comparison of said sub-part signal waveform with corresponding sub-parts of the plurality of database signal waveforms, and determining said expected value of said at least one tissue parameter from a result of said sub-part signal comparison.

10. A method as claimed in claim 1 comprising:
implementing said movement correction as a signal waveform movement correction of at least one MR signal waveform among said plurality of R signal waveforms;
based on a subset of said plurality of MR raw images, determining an expected value of said at least one tissue parameter; and
implementing said signal waveform movement correction by comparing said value of said at least one tissue parameter determined from said at least one MR signal waveform, with said expected value of said at least one tissue parameter, and correcting a sub-part of said at least one MR signal waveform based on a result of said tissue parameter comparison.

11. A method as claimed in claim 10 comprising correcting said sub-part of said at least one MR signal waveform using an ambient MR signal waveform acquired in a spatial environment of said at least one MR signal waveform.

12. A method as claimed in claim 1 comprising implementing said movement correction as a raw image movement correction of at least one MR raw image among the plurality of MR raw images, by:
detecting a first position of the examination object in a first MR raw age among said plurality of MR raw images;
detecting a second position of the examination object in at east one MR raw image among said plurality of MR raw images; and
transforming said at least one MR raw image based on the detected first position and second position.

13. A method as claimed in claim 12 comprising:
from a subset of said plurality of MR raw images, determining an expected value of said at least one tissue parameter, and determining said transformation using a transformation specification that is determined from the detected first position and second position and said expected value of said at least one tissue parameter.

14. A method as claimed in claim 13 comprising including said expected value of said at least one tissue parameter in a regularization term, and determining said transformation specification additionally using said regularization term, to produce a further value of said at least one parameter as a tissue parameter that substantially matches an MR signal waveform generated using the transformed at least one MR raw image.

15. A magnetic resonance (MR) apparatus comprising:
an MR scanner
a control computer configured to operate said MR scanner, while an examination object is situated in the MR scanner, according to an MR fingerprinting sequence to acquire a plurality of MR raw images of an examination area of the examination object;
a processor provided with said MR raw images, said processor being configured to generate a plurality of MR signal waveforms from the MR raw images, with the plurality of MR signal waveforms being formed over different voxels of the plurality of MR raw images;
said processor being configured to access a database in which a plurality of database signal waveforms are stored that are logically linked in said database respectively to a database value of at least one tissue parameter, and to compare said plurality of MR signal waveforms with said plurality of database signal waveforms to obtain a comparison result;
said processor being configured to generate a tissue parameter map based on said comparison result, wherein said tissue parameter map is movement corrected based on a movement correction; and
said processor being configured to make said tissue parameter map available at an output of the processor in electronic form, as a datafile.
